(19) United States
(12) Patent Application Publication
(10) Pub. No.: US 2005/0069815 A1
(43) Pub. Date: Mar. 31, 2005

(54) Processing method and semiconductor manufacturing method

(76) Inventors: Tomoyuki Takeishi, Kawasaki-shi (JP); Kenji Kawano, Yokohama-shi (JP); Hiroshi Ikegami, Hiratsuka-shi (JP); Shinichi Ito, Yokohama-shi (JP); Masami Watase, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/916,414

(22) Filed: Aug. 12, 2004

(30) Foreign Application Priority Data
Aug. 13, 2003 (JP) 2003-292973

(51) Int. Cl. G03F 7/00

(52) U.S. Cl. 430/311; 430/313; 430/323; 430/330

(57) ABSTRACT

A processing method comprises forming a water-soluble protective film on a first film having a processing area above a substrate irradiating processing light on the processing area selectively with to selectively remove the first film in the processing area and the protective film on the processing area, and removing the protective film with water after the selective irradiating.

### CROSS-REFERENCE TO RELATED APPLICATIONS

This application is based upon and claims the benefit of priority from prior Japanese Patent Application No. 2003-292973, filed Aug. 13, 2003, the entire contents of which are incorporated herein by reference.

### BACKGROUND OF THE INVENTION

1. Field of the Invention

The present invention relates to light-irradiation-based processing methods and methods of manufacturing a semiconductor device using the processing methods.

2. Description of the Related Art

As the dimensions of semiconductor devices are scaled down, it has become increasingly essential to increase the accuracy of alignment relative to underlying layers in the lithography steps in a process of manufacturing a semiconductor device.

When a film that underlies a resist layer is great in reflection or absorption of alignment light, it becomes difficult to detect the position of an alignment mark. For example, in the lithography step for formation of metal wiring such as Al wiring, it is impossible to directly detect the position of the alignment mark formed under the Al film. For this reason, the alignment mark itself is previously formed on top with a step and the Al film is then formed on the alignment mark. The alignment is performed by detecting the surface irregularities of the Al film on the alignment mark. However, since the surface irregularities of the Al film become asymmetrical with respect to the underlying irregularities because of the nature of Al deposition methods such as sputtering, evaporation, etc., the alignment error increases in magnitude and the manufacturing yield decreases. Thus, a method has been proposed which selectively removes a film, such as an Al film, which is opaque to alignment light through the use of abrasion technology.

The abrasion technology, which is one of the processing technologies using light such as a laser beam, has received attention recently as a semiconductor device processing technology because it enables fine patterns to be formed without using lithography techniques. The abrasion is a reaction in which, when a film is irradiated with light and the intensity of irradiation reaches a certain threshold, it melts into gas. The use of this reaction allows fine-pattern processing, such as boring, cutting, etc.

When the abrasion technology is used in the semiconductor device manufacturing process, part of films including metal films which is not completely gasified at the time of abrasion is scattered on the periphery of a processing area and adheres to it as particles. The formation of a positive chemically amplified resist film above the processing area (device pattern area) with particles attached thereto results in variations in the thickness of the resist film. For this reason, after exposure and development the resist pattern cannot have desired dimensions. Semiconductor devices fabricated using resist patterns thus formed as masks will have great variations in device performance.

In order to prevent defects due to such particles, a technique has been proposed which involves performing light processing after the formation of a protective film on a film and removing particles together with the protective film after the termination of processing (Japanese Unexamined Patent Publication No. 5-337661).

In this Patent Publication, a heat resistant organic material, such as polyimide, polyamide, etc., is used as a protective film. Such a heat resistance organic material does not dissolve in a solvent, making it difficult to remove the protective film. According to our studies, particles were found to remain on the film even after the removal of the protective film. Depending on mechanical properties of the protective film, film peeling may occur at processing time, which results in processing failures.

### BRIEF SUMMARY OF THE INVENTION

According to an aspect of the invention, there is provided a processing method comprising: forming a water-soluble protective film on a first film having a processing area above a substrate; irradiating processing light on the processing area selectively with to selectively remove the first film in the processing area and the protective film on the processing area; and removing the protective film with water after the selective irradiating.

According to another aspect of the invention, there is provided a processing method comprising: forming an organic film made of an organic resin and having internal stress on a first film formed above a substrate and having a processing area; decreasing the internal stress of the organic film; irradiating processing light on the processing area selectively to selectively remove the organic film on the processing area of the first film; and etching the processing area of the first film using the organic film as a mask, after the irradiation.

According to still another aspect of the invention, there is provided a processing method comprising: applying a film forming solution containing a solvent above a substrate to form a liquid film above a major surface of the substrate; removing part of the solvent contained in the liquid film to form a first film which has a processing area above the alignment mark; irradiating processing light on the processing area selectively to selectively remove the first film in the processing area; and heating the substrate at a first temperature after the irradiating to remove the solvent contained in the first film almost completely.

### BRIEF DESCRIPTION OF THE SEVERAL VIEWS OF THE DRAWING

FIGS. 1A to 1G are sectional views illustrating the steps of manufacture of a semiconductor device according to a first embodiment of the present invention;

FIG. 2 is a diagram illustrating the process of removing the protective film in accordance with the first embodiment;

FIG. 3 is a diagram illustrating a modification of manufacturing steps of the semiconductor device according to the first embodiment;

FIGS. 4A and 4B are diagrams illustrating a modification of manufacturing steps of the semiconductor device according to the first embodiment;

FIGS. 5A to 5D are diagrams illustrating modifications of manufacturing steps of the semiconductor device according to the first embodiment;

FIGS. 6A to 6D are sectional views illustrating the steps of manufacture of a semiconductor device according to a second embodiment of the present invention;

FIGS. 7A to 7D are sectional views illustrating the steps of manufacture of a semiconductor device according to a third embodiment of the present invention; and

FIGS. 8A to 8D are sectional views illustrating the steps of manufacture of a semiconductor device according to a fourth embodiment of the present invention.

### DETAILED DESCRIPTION OF THE INVENTION

Embodiments of the present invention will be described hereinafter with reference to the accompanying drawings.

First Embodiment

hereinafter, a description is given of a pattern forming method which allows desired processing to be performed on a processing area without causing particles produced at the time of light processing to adhere to the periphery of the processing area.

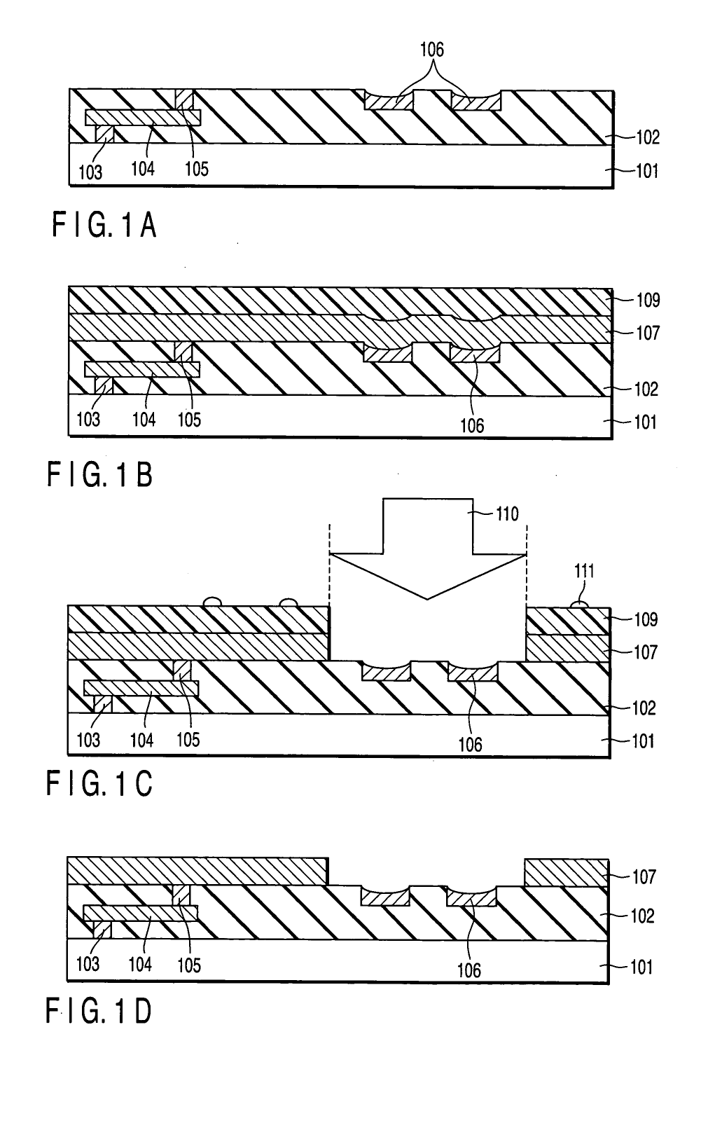

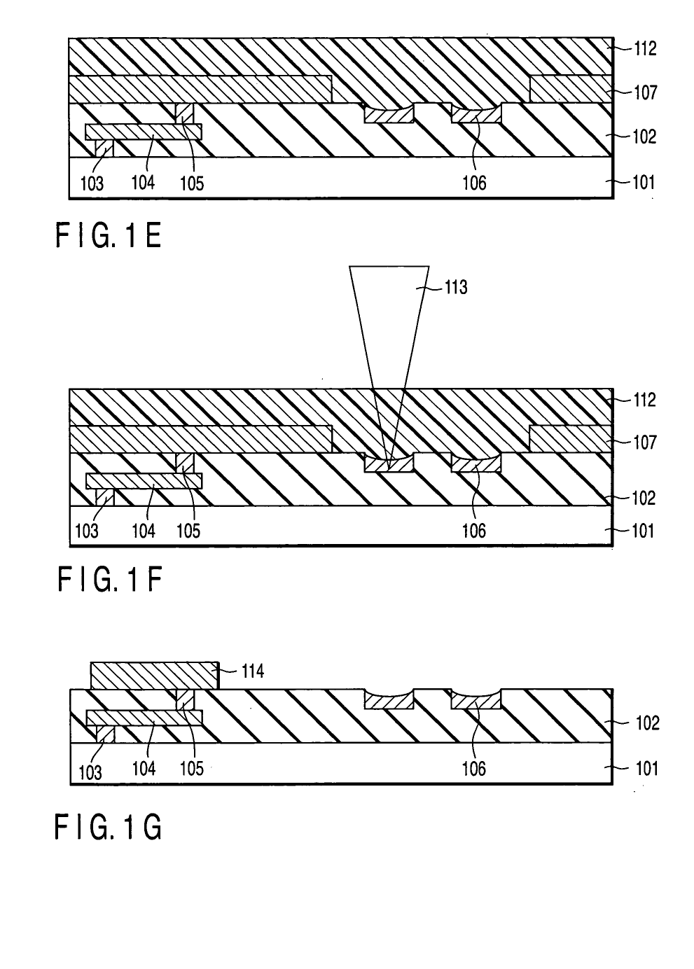

FIGS. 1A to 1G are sectional diagrams illustrating the steps of manufacture of a semiconductor device according to a first embodiment of the present invention.

As shown in FIG. 1A, a semiconductor device at the stage prior to the formation of Al wirings is prepared. In this semiconductor device, an interlayer insulating film 102 is formed on a semiconductor substrate 101. A via plug 105 to be connected to an Al wiring which will be formed later is formed in the interlayer insulating film 102. Alignment marks 106 are formed on the interlayer insulating film. Reference numeral 103 denotes a plug and 104 denotes a lower-level interconnection layer.

As shown in FIG. 1B, an Al film 107 and a protective film 109 are formed in sequence above the surface of the semiconductor device. The thickness of the protective film 109 is 100 nm. The protective film 109 is formed by coating a polyacrylic resin, which is a water-soluble resin, onto the Al film 107 through a rotation coating method and then volatilizing the solvent.

As shown in FIG. 1C, in the atmosphere, an processing area (100×200 μm) under which the alignment marks are formed is irradiated five times with processing light 110. As the result, an opening is formed in the protective film 109 and the Al film 107. The processing light irradiation is carried out so that the protective film 109 will not become glassy. In this embodiment, the processing light 110 is the third harmonic component (355 nm in wavelength) of Q-switch YAG laser. The fluence of the processing light 110 is 0.4 J/cm²·pulse. Reference numeral 111 denotes particles of the protective film 109 and the Al film 107 which have scattered as the result of failure to become completely gasified at abrasion time.

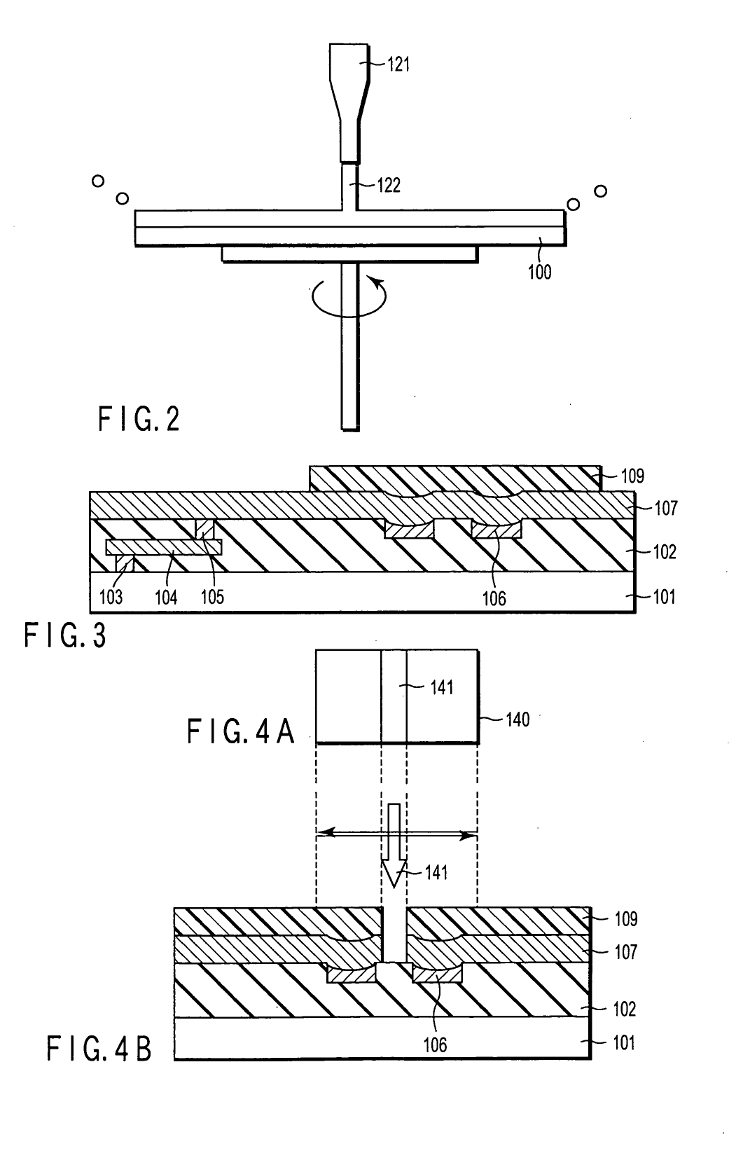

After the light processing, the substrate 101 is carried to a cleaning unit by a carrying robot. As shown in FIG. 1D, the protective film 109 is peeled off by supplying water to it. As shown in FIG. 2, to peel off the protective film 109, pure water 122 is supplied at a flow rate of 1 L/min to the protective film from a nozzle 121 placed above the substrate 101 rotating at 100 rpm. After 60 seconds, the supply of pure water is stopped. After that, to dry the substrate 101, its rotating speed is increased up to 4000 rpm.

SEM observations after the light processing revealed that no particles were left on the Al film 107 above the periphery of the processing area and thus confirmed that good processing was achieved.

As shown in FIG. 1E, an i-line resist film 112 is formed above the surface of the semiconductor substrate 101. As shown in FIG. 1F, the alignment marks 106 is irradiated with alignment light (reference light) 113 to detect its position. Based on the recognized position, a pattern is transferred onto the resist film 112 to form its latent image in the resist film. To form the resist pattern, the resist film formed with the latent image is developed. As shown in FIG. 1G, to form a wiring pattern 114, the Al film 107 is etched using the resist pattern as a mask. The resist pattern is removed after the formation of the wiring pattern 114.

At the light processing time, no particles adhere to the periphery of the processing area. As the result, the wiring pattern of predetermined dimensions will be formed. The manufacturing yield of devices fabricated through subsequent steps will increase and variations in device performance will decrease.

In this embodiment, a polyacrylic resin is used as the protective film. It is desirable that the protective film be water soluble and more transparent to the wavelength of processing light than the Al film. Since the highly transparent protective film is used, the processing light will be little absorbed by the protective film. As the result, the heat generated by the protective film itself is reduced. For this reason, part of the protective film which failed of decomposition at light irradiation time will be scattered to the periphery of the processing area in the state of solid without being melted. The protective film scattered just in the state of solid to the periphery of the processing area is quickly removed by water cleaning after light processing. In addition, the protective film, being soluble in water, can be removed relatively inexpensively.

When the protective film is less transparent to processing light than the Al film, the processing light will be absorbed by the protective film with the result that the protective film itself generates heat and melts. Thus, the melted protective film adheres as particles to the protective film in the periphery of the processing area and the particles will change their nature or be deposited to the underlying Al film through their heat. As the result, even at the time of removing the protective film it becomes impossible to remove the protective film in areas to which the melted particles have adhered. Thus, defects result.

Although the embodiment has been described as using a polyacrylic resin for the protective film, this is not restrictive. It is required only that the material of the protective film be less in absorption of processing light than the film to be processed. Suppose that the extinction coefficients of the protective film and the film to be processed at the wavelength λ(nm) of processing light are k and k′, respectively. Then, it is only required to select a material of the protective film and processing light which satisfy the following relationship:
k<k′ (1)

In the case of 355 nm in wavelength, the extinction coefficient of polyacrylic resin is 1.0×10⁻⁴ and the extinction coefficient of Al is 3.36.

Moreover, it is desirable that the protective film irradiated with laser light be able to maintain the solid state. It is therefore desirable that the protective film be kept below the melting point (Tm) when it is irradiated with a pulse of laser light. It is recommended to select a material and processing light to satisfy the following relationships:
Tm>T0+ΔT (2)
ΔT={α(1−R_{F}/100)F/C_{F}} (3)
α=4πk/λ (4)
where Tm(K) is the melting point of the protective film, T0(K) is the atmospheric temperature, ΔT(K) is the difference in temperature between the protective film after light irradiation and the protective film prior to light irradiation, α (1/nm) is the absorption coefficient of the protective film, R_{F}(%) is the reflectance of the protective film, F (J/cm²·pulse) is the fluence of processing light, CF (J/cm³·K) is the specific heat of the protective film, k is the extinction coefficient of the protective film, and λ (nm) is the wavelength of laser light.

The property values of a polyacrylic resin for 355 nm of laser light are indicated in the following table:

TABLE 1

| Specific heat | Refractive | Extinction | | |
|---|---|---|---|---|
| (J/cm³K) | index | coefficient | Reflectance | Tm (° C.) |
| 0.07 | 1.44 | 1.0 × 10⁻⁴ | 3.25 | 200.00 |

Even in the event that particles of a protective film melted by light processing adhere to the processing area, a material that keeps water solubility may be used as the protective film. For example, an organic material having a hydrophilic group, such as a hydroxyl group, carboxyl group, or amino group, or a water soluble inorganic material is used as a material of the protective film. A protective film having such properties can be used as the protective film in the present embodiment because it can be removed in the water washing step subsequent to light processing.

In this embodiment, the third harmonic component of Q-switch YAG laser is used as a light source for light processing. As the light source, use may be made of the fourth harmonic component (266 nm) of the Q-switch YAG laser, a pulsed laser, such as a KrF excimer laser, or a lamp. In the embodiment, for laser processing the semiconductor substrate is irradiated five times with light of 0.4 J/cm²·pulse. It is required only that the fluence and the number of irradiations be set so that no residues are present in the processing area or the metal film to be processed is not damaged.

In the embodiment, a metal film is processed. The film to be processed is not limited to a metal film. Films to be processed include metal oxide films, antireflection films, metal films, silicon nitride films, silicon carbide films, silicon oxide films, and polycrystalline silicon films.

In the embodiment, an i-line resist film is formed after light processing and then patterned. This is not restrictive. Any other resist, such as KrF resist, ArF resist, EB resist, etc., may be used.

In the embodiment, the protective film is formed above the entire surface. As shown in FIG. 3, the protective film may be selectively formed only in a desired position. To selectively form the protective film, use may be made of a method described in, for example, U.S. Pat. No. 6,231,917. Any other method can be used provided that it can selectively form a thickness-controlled protective film above a substrate.

In the embodiment, at light processing time, the irradiated area is made equal in size to the processing area. As shown in FIGS. 4A and 4B, the substrate may be scanned with processing light 141 the planar shape on the substrate of which is in the form of a strip. In this case, to scan one of the processing light and the substrate with respect to the other, the substrate may be moved with the optical axis fixed. Alternatively, the optical axis may be moved by translating a shape-controlled slit (aperture). Reference numeral 140 denotes the processing area. FIG. 4A is a sectional view and FIG. 4B is a plan view of the processing area.

For example, in the atmosphere, a mask having a slit of 100 by 5 μm is placed between a processing area (100 by 200 μm) and a light source. The third harmonic component (355 nm) of a Q-switch YAG laser as the light source is directed onto the processing area. The processing light has a fluence of 1.0 J/cm² pulse and an oscillating frequency of 250 Hz. To remove the protective film and the Al film in the processing area, the mask is moved at a speed of 500 μm/sec from one end of the processing area to the other end.

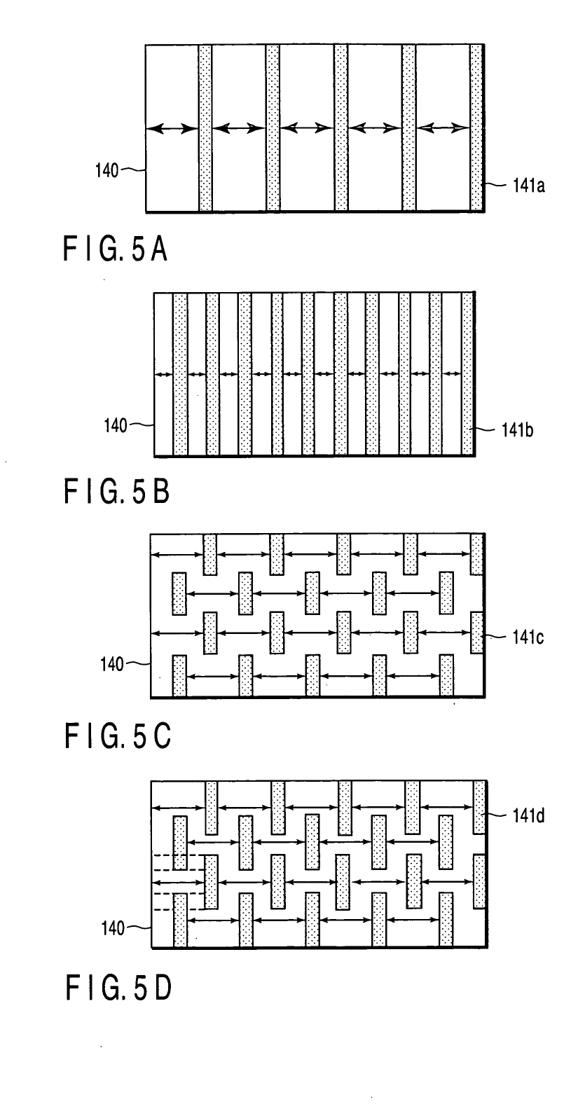

Usually, particles are produced by gas generated by abrasion expanding and then blowing off that part of a film underlying the protective film which has not been gasified. The amount of gas generated by light irradiation per pulse while pulsed laser light in the shape of a strip is scanned with the processing area is smaller than that when laser light is directed at a time onto the entire processing area. For this reason, it becomes possible to inhibit particles that adhere to the periphery of the processing area from increasing in number and the protective film from peeling off at the boundary of the processing area. As shown in FIGS. 5A and 5B, a plurality of processing light beams 141a and 141b each in the shape of a strip may be arranged at regularly spaced intervals in the scanning direction. As shown in FIGS. 5C and 5D, a plurality of processing light beams 141c and 141d each in the shape of a dot may be arranged at regularly spaced intervals in both the scanning direction and the direction normal to the scanning direction. As shown in FIG. 5, processing light beams 141d which are adjacent to each other in the scanning direction may be arranged so that they overlap each other in the direction normal to the scanning direction.

The strip or dot is a quadrilateral in which the length in the scanning direction is shorter than the length of the processing area. In particular, with the strip, the length in the direction normal to the scanning direction is approximately equal to the length of the processing area in the direction normal to the scanning direction. The dot is a quadrilateral in which the length in the scanning direction is shorter than the length of the processing area. With the strip, the length in the direction normal to the scanning direction is shorter than the length of the processing area in the direction normal to the scanning direction.

Second Embodiment

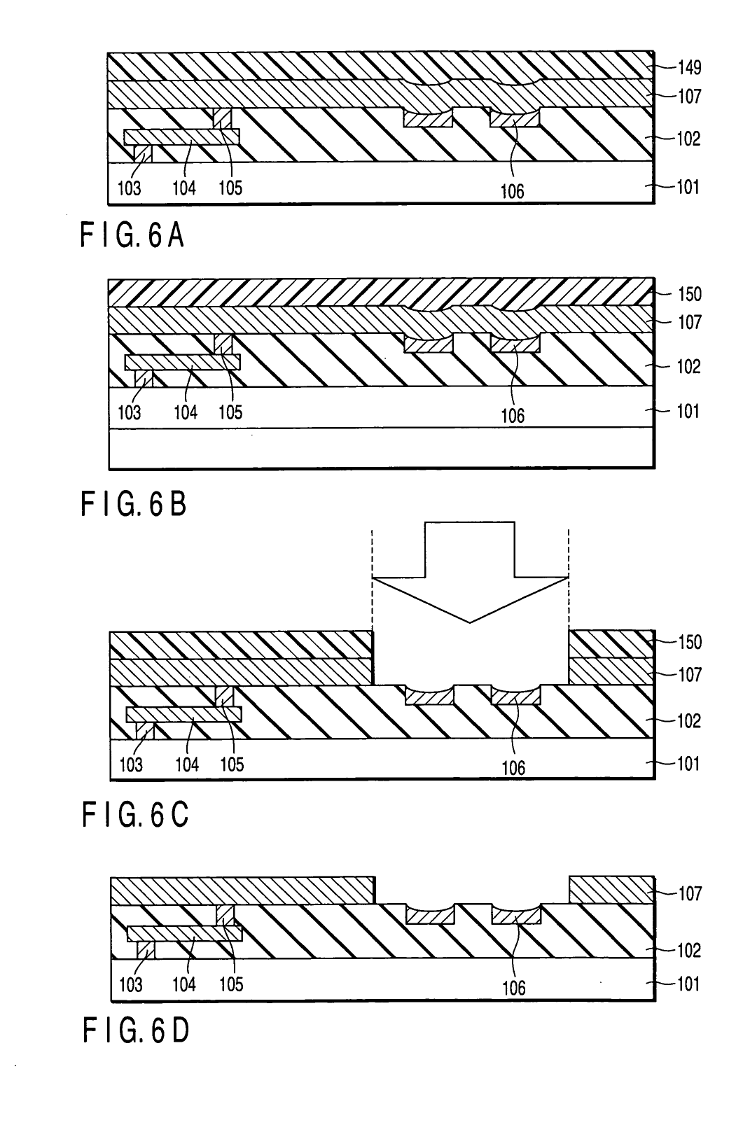

FIGS. 6A to 6D are sectional views illustrating the steps of manufacture of a semiconductor device according to a second embodiment of the present invention.

First, as shown in FIG. 6A, an organic film 149 the main component of which is a novolak resin (organic material) containing a thermal decomposition agent is formed on an Al film 107 by means of the rotation coating method. Next, using a hot plate, the substrate is heated for 60 seconds at 100° C. to volatilize the solvent in the organic film 149. Here, the thermal decomposition agent acts as the catalyst of the thermal decomposition reaction to disconnect the principal chain of the resin. Any material that is able to decompose the organic film forming resin can be used as the thermal decomposition agent.

Next, the substrate is heated for 60 seconds at 150° C. to obtain an organic film 150 as shown in FIG. 6B. Here, the thermal decomposition agent acts as the catalyst to thermally decompose the organic film forming resin. The principal chain of the resin is disconnected by the thermal decomposition reaction, which results in a reduction in its molecular weight. As the result, the internal stress of the organic film 150 is lowered.

As shown in FIG. 6C, to form an opening in the resin film 150, processing light, which is the third harmonic component of Q-switch YAG laser, is directed five times onto a processing area (100 by 200 μm). The fluence of the processing light is 0.6 J/cm²·pulse.

Next, as shown in FIG. 6D, the Al film is selectively removed by means of wet etching using the resin film 150 as a mask. At the time of etching, no processing failures due to film peeling occurred.

After the resin film has been removed, an I-line resist film is formed on the Al film 107 as in the first embodiment. The alignment marks 106 are irradiated with alignment light (reference light) to recognize their position. Exposure is made on the basis of the position of the alignment marks 106. To form a resist pattern, the resist film is developed. To form a wiring pattern, the Al film 107 is etched using the resist pattern as a mask.

At light processing time, particles will not adhere to the periphery of the processing area. As the result, a wiring pattern of predetermined dimensions can be formed. The manufacturing yield of devices fabricated through subsequent steps will increase and variations in device performance will decrease.

Thus, the internal stress of the organic film is reduced by disconnecting the principal chain of the resin through the thermal decomposition reaction, allowing even a material that is great in internal stress to be used as the protective film.

The thermal decomposition agent in the present embodiment contains one which initiates the reaction in the temperature range from the organic film deposition temperature (100° C. in this embodiment) to 200° C. When the reaction initiation temperature of the thermal decomposition agent is lower than the deposition temperature, the heat treatment at deposition time will promote the decomposition of the novolak resin, causing the processing characteristics to deteriorate. When the reaction initiation temperature is above 200° C., the novolak resin will be oxidized, which may cause the film characteristics to deteriorate. It is therefore desirable that the reaction initiation temperature range from the deposition temperature to 200° C. When the amount of the thermal decomposition agent is too small, the decomposition reaction proceeds very little; thus, no change is observed in light processing characteristics and film peeling occurs. When the amount of the thermal decomposition agent is too large, the decomposition reaction is promoted, which may cause the resistance to chemicals to degrade at the wet etching time after light processing. It is therefore desirable that the amount of the thermal decomposition agent added to the novolak resin lie in an appropriate range.

With the pattern forming method of the first embodiment, to allow the protective film irradiated with processing light to maintain the solid state, restrictions may be imposed on the fluence of the processing light. As the result, the fluence of the processing light may become insufficient to process the metal film. According to the pattern formation method of the first embodiment, however, the fluence of processing light sufficient to process the metal film can be set because it is not associated with the selective removal of the organic film.

In the present embodiment, the process of changing the nature of the organic film is carried out through heating by the hot plate. This is not restrictive. Heating may be performed by irradiating the organic film with infrared radiation. Any other method may be used that can heat the organic film.

The process of changing the nature of the organic film is not limited to heating. The decomposition agent contained in the organic film may be activated by being irradiated with energy radiation so that it acts as the catalyst to decompose the resin that forms the organic film. As the decomposition agent any material can be used provided that it can be activated by being irradiated with energy radiation, such as ultraviolet radiation, far ultraviolet radiation, deep ultraviolet radiation, electron beam, etc., and bring about the resin decomposition reaction. In the embodiment, light processing is performed in the atmosphere, but it may be performed in flowing water.

The etching of the metal film after light processing of the organic film is not limited to wet etching used in this embodiment. For example, dry etching or anisotropic etching may be used. It is advisable to select the most suitable etching method according to the properties of a metal film to be etched.

In the embodiment, a metal film is processed. The film to be processed is not limited to a metal film. Films to be processed include metal oxide films, antireflection films, metal films, silicon nitride films, silicon carbide films, silicon oxide films, and polycrystalline silicon.

In the embodiment, an i-line resist film is formed after light processing. Instead, KrF resist, ArF resist, or EB resist may be formed.

In the embodiment, the irradiated area is made equal in size to the processing area at light processing time. As in the first embodiment, the processing light may be shaped in the form of a strip or dot on the substrate and moved relative to the substrate.

Third Embodiment

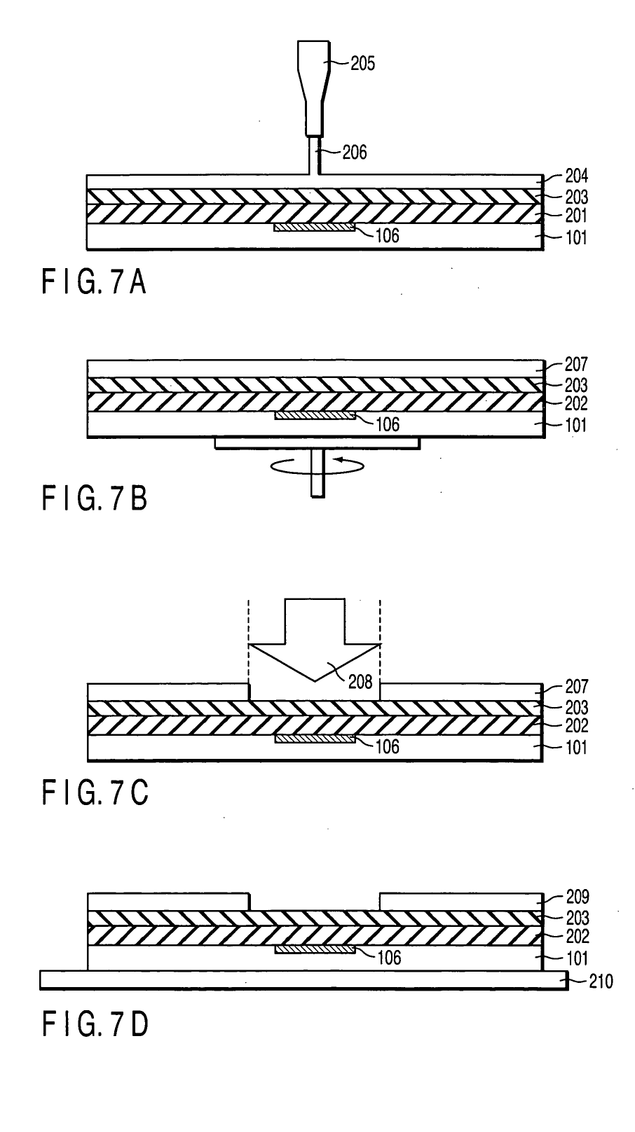

FIGS. 7A to 7D are sectional views illustrating the steps of manufacture of a semiconductor device according to a third embodiment of the present invention. In these drawings, there is illustrated only an area in which an alignment mark is formed.

As shown in FIG. 7A, to form a film 204 in the form of a liquid, an antireflection film forming chemical 206 containing a solvent and an antireflection material is applied from a nozzle 205 to the surface of an SiO₂ film 203 formed above a semiconductor substrate 101 that is rotating. Reference numeral 106 denotes an alignment mark formed in the semiconductor substrate 101 and 201 denotes a silicon nitride film.

Next, as shown in FIG. 7B, an antireflection film 207 having part of the solvent removed from the liquid film 204 is obtained through spin drying involving rotating the semiconductor substrate 101. To obtain the antireflection film 207, part of the solvent may be removed by placing the semiconductor substrate 101 formed on top with the liquid film 204 in a low-pressure atmosphere.

Next, as shown in FIG. 7C, to form an opening in the antireflection film 207, an processing area (100 by 200 μm) is irradiated five times with processing light 208 in the atmosphere. The opening is formed over the alignment mark. After light processing, the periphery of the processing area was observed with a scanning electron microscope (SEM). We confirmed that good processing was achieved because no particles remained in the periphery of the processing area of the antireflection film. The processing light 208 is the third harmonic component (355 nm in wavelength) of Q-switch YAG laser and its fluence is 0.4 J/cm²·pulse.

Next, as shown in FIG. 7D, the semiconductor substrate 101 is placed on a hot plate 210. To obtain desired antireflection characteristics, the semiconductor substrate is heated for 120 seconds at 300° C., allowing an antireflection film 209 which has the solvent almost completely removed to be obtained.

A positive chemically amplified resist of 200 nm in thickness for ArF light (193 nm in wavelength) is formed on the antireflection film 209. The semiconductor substrate 101 is then carried to an exposure apparatus having an ArF excimer laser as the light source. The position of the alignment mark 106 is recognized by being irradiated with alignment light (reference light) through an exposure reticle. A gate processing pattern is transferred onto the resist according to the position of the alignment mark 106. The pattern-transferred resist is developed to form a gate processing resist pattern. A gate processing pattern is formed in the SiO₂ film 203 using the developed resist as a mask.

At the light processing time, no particles adhere to the periphery of the processing area. As the result, gates pattern of predetermined dimensions can be formed. The manufacturing yield of devices fabricated through subsequent steps will increase and variations in device performance will decrease.

The third embodiment is characterized by performing light processing on an antireflection film in a state where the solvent has not be completely removed. The antireflection film in which the solvent remains will evaporate quickly. After light processing, no particles are present on the antireflection film in the periphery of the processing area.

When light processing is performed on an antireflection film having the solvent removed completely, particles will adhere to the antireflection film in the periphery of the processing area because the antireflection film is difficult to evaporate. Some antireflection films exhibit the antireflection property by bringing about a crosslinking reaction upon heating. Such antireflection films become more difficult to evaporate at the light processing time; thus, more particles will result.

The processing light is not limited to the third harmonic component of Q-switch YAG laser. For example, as the processing light use may be made of the fourth harmonic component (266 nm) of the Q-switch YAG laser, pulsed laser light from a KrF excimer laser, or lamp light. The conditions of light processing are not limited to the abovementioned conditions. It is required only that the fluence and the number of irradiations be set so that no residues are present in the processing area or the film underlying the antireflection film is not damaged. The light processing may be performed in a state where a flow of liquid or air is formed on the processing area.

In the embodiment, the irradiated area is made equal in size to the processing area at light processing time. As described in the first embodiment, the processing area may be scanned with processing light shaped in the form of a strip.

The embodiment has been described as processing an antireflection film. Processing may be performed on a coated film, such as a resist film, a silicon oxide film, a polyimide film, or the like.

Fourth Embodiment

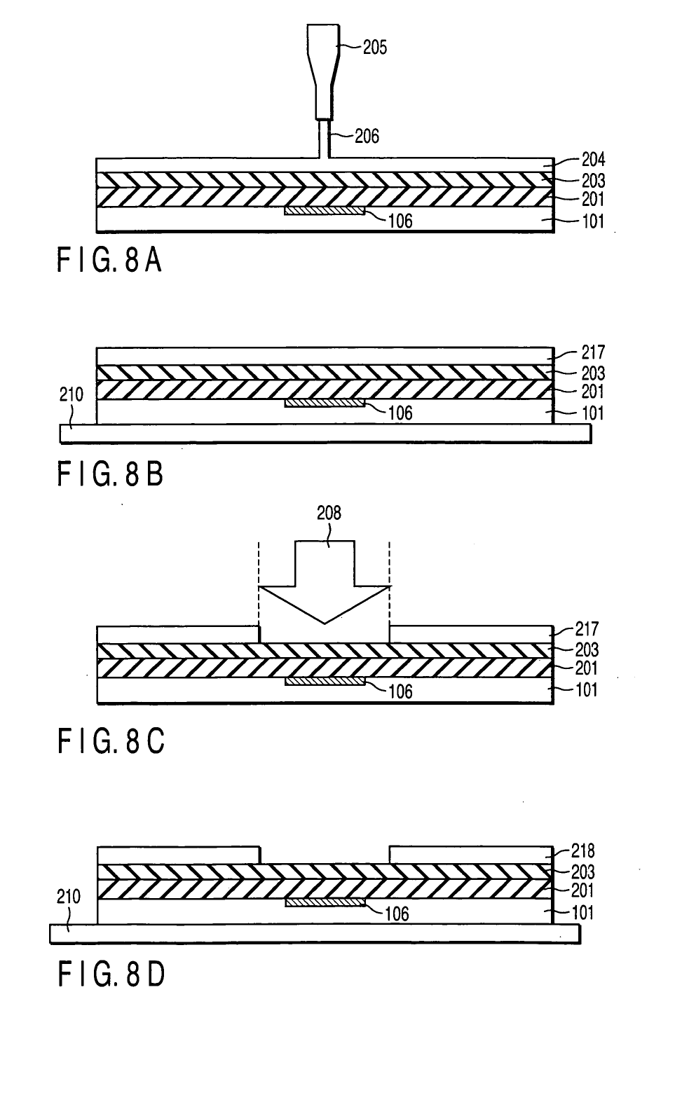

FIGS. 8A to 8D are sectional views illustrating the steps of manufacture of a semiconductor device according to a fourth embodiment of the present invention. In these figures, corresponding parts to those in FIGS. 1A to 1D are denoted by like reference numerals and descriptions thereof are omitted.

First, as shown in FIG. 8A, to form a liquid film 204, an antireflection film forming chemical 206 containing a solvent is applied to the surface of an SiO₂ film 203 through rotation coating. After that, an antireflection film 217 having part of the solvent removed from the liquid film 204 is formed through spin drying. To remove part of the solvent from the liquid film 204, the semiconductor substrate 101 formed on top with the liquid film 204 may be placed in a low-pressure atmosphere.

Next, as shown in FIG. 8B, the semiconductor substrate 101 is placed on a hot plate 210 and then heated for 60 seconds at 150° C. Heating allows the antireflection film 217 having part of the solvent removed to be obtained. In order for the antireflection film used in this embodiment to provide antireflection characteristics required for the lithographic step, it is usually required to heat the semiconductor substrate at 300° C. At this stage, however, the temperature at which the substrate is heated is set lower than 300° C.

Next, as shown in FIG. 8C, to form an opening in the antireflection film 217, an processing area (100 by 200 μm) is irradiated five times with processing light 208 in the atmosphere. The opening is formed above the alignment mark. After light processing, the periphery of the processing area was observed with a scanning electron microscope (SEM). We confirmed that good processing was achieved because no particles remained in the periphery of the processing area of the antireflection film. The processing light 208 is the third harmonic component (355 nm in wavelength) of Q-switch YAG laser and its fluence is 0.4 J/cm²·pulse.

Next, as shown in FIG. 8D, the semiconductor substrate 101 is placed on the hot plate 210 and then heated for 120 seconds at 350° C., allowing an antireflection film 218 which has the solvent almost completely removed and in which crosslinking has been set up to be obtained.

After the above processes, a positive chemically amplified resist of 200 nm in thickness for ArF light (193 nm in wavelength) is formed on the antireflection film 218. The position of the alignment mark 106 is then recognized by being irradiated with alignment light (reference light) through an exposure reticle. A gate processing pattern is transferred onto the resist according to the position of the alignment mark 106. The pattern-transferred resist is developed to form a gate processing resist pattern. A gate processing pattern is formed in the SiO₂ film 203 using the resist pattern as a mask.

At the light processing time, no particles are produced in the periphery of the processing area. As the result, gates pattern of predetermined dimensions can be formed. The manufacturing yield of devices fabricated through subsequent steps will increase and variations in device performance will decrease.

The coated film immediately after spin drying contains the solvent in large quantities. The light processing in this state may cause the antireflection film to peel off. In this embodiment, since the substrate is heated at a temperature lower than usual to remove part of the solvent, no the antireflection film will not peel off.

In this embodiment, the heating temperature for removing part of the solvent is 150° C. As described in connection with the third embodiment, when the heating temperature is too high, the antireflection film becomes difficult to evaporate at light processing time and particles are liable to adhere to the antireflection film in the periphery of the processing area. In particular, with a material which, when heated, brings about crosslinking, the adhesion of particles becomes remarkable. In performing light processing on such an antireflection film, it is desirable that the heating temperature prior to the light processing be below the crosslinking temperature.

When the heating temperature is too low, the solvent remains in large quantities in the film depending on the material, causing the film strength to degrade. For this reason, film peeling may occur at light processing time. It is therefore required that the substrate heating temperature prior to light processing be in the range from a temperature at which the shape of the processing area is not affected to less than the crosslinking temperature of the antireflection film.

In this embodiment, the third harmonic component of Q-switch YAG laser is used as a light source for light processing. This is not restrictive. As the light source, use may be made of the fourth harmonic component (266 nm) of the Q-switch YAG laser, a pulsed laser, such as a KrF excimer laser, or a lamp. In the embodiment, the semiconductor device is irradiated five times with light of 0.4 J/cm²·pulse. It is required only that the fluence and the number of irradiations be set so that no residues are present in the processing area or the interlayer insulating film formed under the antireflection film is not damaged. In the embodiment, light processing is performed in the atmosphere, but it may be performed in flowing water.

In the embodiment, the irradiated area is made equal in size to the processing area at light processing time. As described in the first embodiment, the processing area may be scanned with processing light shaped in the form of a strip.

The embodiment has been described as processing an antireflection film. Processing may be performed on a coated film, such as a resist film, a silicon oxide film, a polyimide film, or the like.

To form the antireflection film 207, one or more processes selected from the group consisting of the spin drying process, pressure reducing process, and heating process at a second temperature may be used in combination.

Although the embodiments of the invention have been described in terms of one specific application to the manufacture of a semiconductor device, the principles of the invention are adaptable to other applications. Each of the embodiments described above represents an example of the alignment mark formed under the processing area. However, a registration mark may be formed instead of the alignment mark.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A processing method comprising:
forming a water-soluble protective film on a first film having a processing area above a substrate;
irradiating processing light on the processing area selectively with to selectively remove the first film in the processing area and the protective film on the processing area; and
removing the protective film with water after the selective irradiating.

2. The processing method according to claim 1, wherein the extinction coefficient k of the protective film for the wavelength λ of the processing light is smaller than the extinction coefficient k′ of the first film for the wavelength λ.

3. The processing method according to claim 2, wherein the selective irradiation is performed under the following conditions:
Tm>T₀+ΔT
ΔT={α(1−R_{F}/100)F/C_{F}}
α=4πk/λ
where C_{F} is the specific heat of the protective film, α is the absorption coefficient of the protective film, k is the extinction coefficient of the protective film, RF is the reflectance of the protective film, ΔT is the difference between the temperatures of the protective film before and after the selective irradiation, Tm is the melting point of the protective film, T₀ is the atmospheric temperature, F is the fluence of the processing light, and λ is the wavelength of the processing light.

4. The processing method according to claim 1, wherein the protective film in the periphery of the processing area has the property of maintaining water solubility even after selective removal thereof.

5. The processing method according to claim 1, wherein the protective film is formed of an organic material having a hydrophilic group.

6. The processing method according to claim 1, wherein the protective film is formed of an inorganic material.

7. The processing method according to claim 1, wherein the protective film is selectively formed above a portion of the substrate.

8. The processing method according to claim 1, wherein the irradiation is performed in a state where a flow of air or liquid is formed above the processing area.

9. The processing method according to claim 1, wherein the substrate includes an alignment mark or registration mark under the processing area of the first film.

10. The processing method according to claim 1, wherein the first film is selected from the group consisting of an antireflection film, a metal film, a metal oxide film, a silicon nitride film, a silicon carbide film, a silicon oxide film, and a polycrystalline silicon film.

11. The processing method according to claim 1, wherein the processing light is laser light or lamp light.

12. The processing method according to claim 1, wherein the processing light has a planar shape on the substrate, the planar shape of the processing light is smaller than a planar shape of the processing area, and the processing area is scanned with processing light.

13. The processing method according to claim 12, wherein the planar shape of the processing light is a quadrilateral the width of which in a scanning direction of the processing light is smaller than the width of the processing area in the scanning direction.

14. The processing method according to claim 12, wherein the processing light irradiate positions in a processing area, and the positions are arrayed at regularly spaced intervals along the arrangement direction of the block along the scanning direction.

15. A processing method comprising:
forming an organic film made of an organic resin and having internal stress on a first film formed above a substrate and having a processing area;
decreasing the internal stress of the organic film;
irradiating processing light on the processing area selectively to selectively remove the organic film on the processing area of the first film; and
etching the processing area of the first film using the organic film as a mask, after the irradiation.

16. The processing method according to claim 15, wherein the organic film contains a decomposition initiation agent that acts as a catalyst for a decomposition reaction to disconnect the principal chain of the organic resin.

17. The processing method according to claim 16, wherein the organic film is heated in order to decrease its internal stress and promote the decomposition reaction.

18. The processing method according to claim 16, wherein the organic film is irradiated with energy radiation in order to decrease its internal stress and promote the decomposition reaction.

19. The processing method according to claim 18, wherein the energy radiation is ultraviolet radiation, far ultraviolet radiation, deep ultraviolet radiation, or an electron beam.

20. The processing method according to claim 15, wherein the irradiation is performed in a state where a flow of air or liquid is formed above the processing area.

21. The processing method according to claim 15, wherein the substrate includes an alignment mark or registration mark under the processing area of the first film.

22. The processing method according to claim 15, wherein the first film is selected from the group consisting of an antireflection film, a metal film, a metal oxide film, a silicon nitride film, a silicon carbide film, a silicon oxide film, and a polycrystalline silicon film.

23. The processing method according to claim 15, wherein the processing light is laser light or lamp light.

24. The processing method according to claim 15, wherein the processing light has a planar shape on the substrate, the planar shape of the processing light is smaller than a planar shape of the processing area, and the processing area is scanned with processing light.

25. The processing method according to claim 24, wherein the planar shape of the processing light is a quadrilateral the width of which in a scanning direction of the processing light is smaller than the width of the processing area in the scanning direction.

26. The processing method according to claim 24, wherein the processing light irradiate positions in a processing area, and the positions are arrayed at regularly spaced intervals along the arrangement direction of the block along the scanning direction.

27. A processing method comprising:
applying a film forming solution containing a solvent above a substrate to form a liquid film above surface of the substrate;
removing part of the solvent contained in the liquid film to form a first film which has a processing area above the alignment mark;
irradiating processing light on the processing area selectively to selectively remove the first film in the processing area; and
heating the substrate at a first temperature after the irradiating to remove the film contained in the first film almost completely.

28. The processing method according to claim 27, wherein one or more processes selected from the group including of a spin dry process, a pressure-reducing process, and a heating process at a second temperature are combined in order to remove part of the solvent contained in the liquid film.

29. The processing method according to claim 28, wherein the second temperature is lower than the first temperature.

30. The processing method according to claim 27, wherein the irradiating is performed in a state where a flow of air or liquid is formed above the processing area.

31. The processing method according to claim 27, wherein the substrate includes an alignment mark or registration mark under the processing area of the first film.

32. The processing method according to claim 27, wherein the first film is selected from the group consisting of an antireflection film, a metal film, a metal oxide film, a silicon nitride film, a silicon carbide film, a silicon oxide film, and a polycrystalline silicon film.

33. The processing method according to claim 27, wherein the processing light is laser light or lamp light.

34. The processing method according to claim 27, wherein the processing light has a planar shape on the substrate, the planar shape of the processing light is smaller than-a planar shape of the processing area, and the processing area is scanned with processing light.

35. The processing method according to claim 34, wherein the planar shape of the processing light is a quadrilateral the width of which in a scanning direction of the processing light is smaller than the width of the processing area in the scanning direction.

36. The processing method according to claim 34, wherein the processing light irradiate positions in a processing area, and the positions are arrayed at regularly spaced intervals along the arrangement direction of the block along the scanning direction.

37. A semiconductor device manufacturing method comprising:
preparing a body including a semiconductor substrate having a major surface and an alignment mark above the major surface of the semiconductor substrate;
forming a first film above the major surface of the semiconductor substrate, the first film having a processing area above the alignment mark;
forming a water-soluble protective film on the first film;
irradiating processing light above the processing area selectively to selectively remove the protective film on the processing area and the first film in the processing area;
removing the protective film using water, after the irradiating of the processing light;
forming a photosensitive film on the first film, after the removing;
irradiating reference light above the alignment mark to recognize its position;
irradiating energy radiation on the photosensitive film in the predetermined position on the basis of the position of the alignment mark to form a latent image in the photosensitive film; and
developing the photosensitive film formed with the latent image.

38. A semiconductor device manufacturing method comprising:
preparing a body including a semiconductor substrate having a major surface and an alignment mark above the major surface of the semiconductor substrate;
forming a first film above the major surface of the semiconductor substrate, the first film having a processing area above the alignment mark;
forming an organic film having an internal stress on the first film;
decreasing the internal stress of the organic film;
irradiating processing light on the processing area selectively to selectively remove the organic film after the decreasing;
etching the first film using the organic film as a mask, after the removing of the organic film;
removing the organic film after the etching of the first film;
forming a photosensitive film on the first film after the removing of the organic film;
irradiating the alignment mark with reference light to recognize its position after forming of the photosensitive film;
irradiating energy radiation on the photosensitive film in the predetermined position on the basis of the position of the alignment mark to form a latent image in the photosensitive film; and
developing the photosensitive film formed with the latent image.

39. A semiconductor device manufacturing method comprising:
preparing a body including a semiconductor substrate and an alignment mark above a major surface of the semiconductor substrate;
applying a film forming solution containing a solvent above the major surface of the semiconductor substrate to form a liquid film above the major surface of the substrate;
removing part of the solvent contained in the liquid film to form a first film which has a processing area above the alignment mark;
irradiating processing light on the processing area selectively to selectively remove the first film in the processing area;
heating the first film at a first temperature to remove the solvent contained in the first film almost completely after the irradiating of the processing light;
forming a photosensitive film on the first film after the heating;
irradiating reference light above the alignment mark to recognize a position of the alignment mark;
irradiating energy radiation on the photosensitive film in the predetermined position on the basis of the position of the alignment mark to form a latent image in the photosensitive film; and
developing the photosensitive film formed with the latent image.

40. The processing method according to claim 41, wherein one or more processes selected from the group consisting of a spin dry process, a pressure-reducing process, and a heating process at a second temperature are combined in order to remove part of the solvent contained in the liquid film.

41. The processing method according to claim 40, wherein the second temperature is lower than the first temperature.
